(19) United States
(12) Patent Application Publication
(10) Pub. No.: US 2009/0267234 A1
(43) Pub. Date: Oct. 29, 2009

(54) Semiconductor Device and Method of Manufacturing a Semiconductor Device

(75) Inventor: Viet Nguyen Hoang, Leuven (BE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/306,032

(22) PCT Filed: Jun. 15, 2007
(86) PCT No.: PCT/IB2007/052291

§ 371 Date: Dec. 22, 2008

(30) Foreign Application Priority Data
Jun. 21, 2006 (EP) 06115818.4

(51) Int. Cl. H01L 23/522; H01L 21/768

(52) U.S. Cl. 257/773; 438/637; 257/E23.145; 257/E21.579

(57) ABSTRACT

The invention relates to a semiconductor device comprising a substrate (1) and at least one interconnect layer located at a surface of the substrate (1), the interconnect layer comprising a first wire (20″) and a second wire (20′) which are located in the interconnect layer, the first wire (20″) having a first thickness (T1) and the second wire (20′having a second thickness (T2) that is different from the first thickness, the thickness (T1,T2) being defined in a direction perpendicular to said surface. The invention further relates to a method of manufacturing a semiconductor device comprising a substrate (1) and an interconnect layer located at a surface of the substrate (1), the interconnect layer comprising a first wire (20″) and a second wire (20) which are located in the interconnect layer.

The invention relates to a semiconductor device comprising a substrate and at least one interconnect layer located at a surface of the substrate, the interconnect layer comprising a first wire and a second wire which are located in the interconnect layer. The invention further relates to a method of manufacturing a semiconductor device comprising a substrate and an interconnect layer located at a surface of the substrate, the interconnect layer comprising a first wire and a second wire which are located in the interconnect layer.

Various semiconductor devices and methods of manufacturing a semiconductor device of the kind set forth in the opening paragraph are known, for example from US2006/0049498A1. This document discloses a method of manufacturing a dual damascene structure, which forms a trench first. The manufacturing method has the following steps. First, a substrate with a plurality of semiconductor devices is provided. A first metal layer, a first etching stop layer, a dielectric layer, and a second etching stop layer are subsequently formed thereon. Then a trench is formed in the dielectric layer at a predetermined depth, and a sacrificial layer is filled therein and is subsequently planarized. Then a photoresist layer is formed thereon for etching a via. Afterwards, the photoresist layer and the sacrificial layer are both removed. Following this, the first etching stop layer is etched through to expose the first metal layer. Finally, the via and the trench are filled with a second metal layer. By this sequence of steps a semiconductor device is formed that comprises a wire having a predetermined thickness.

A drawback of the known semiconductor device is that the packing density is relatively low.

It is a first object of the invention to provide a semiconductor device of the kind set forth in the opening paragraph, having an improved packing density.

It is a second object of the invention to provide a method of manufacturing such a semiconductor device.

The invention is defined by the independent claims. The dependent claims define advantageous embodiments.

With the semiconductor device according to the invention the first object is realized by the first wire having a first thickness and the second wire having a second thickness that is different from the first thickness, the thickness being defined in a direction perpendicular to said surface. In order to provide enough routing resources semiconductor devices generally comprise multiple interconnect layers. Each layer then comprises wires being isolated from each other with dielectrics and/or airgaps. In today's technologies wires within the same interconnect layer have the same thickness. In an integrated circuit different interconnects need to carry different amounts of current. Within one interconnect layer, because all the wires have the same thickness, the only way to adapt a wire to the current it is supposed to carry is to change its width. In this way, the current density within the interconnect remains below the threshold before running into reliability problems. However, a major disadvantage of changing the width of interconnects within one metal level is that the packing density is reduced. In other words, surface area in the integrated circuit is consumed by wide wires that need to carry large currents. A good example of such a situation is, when in the first metallization layer of an integrated circuit power lines co-exist along side signal wires. The power lines need a significantly larger wire width than the signal wires, which consumes a lot of surface area.

The semiconductor device according to the invention solves this problem by using wires having different thicknesses integrated into one interconnect layer. By doing so, thick wires can be used for wires that need to carry large currents and thinner wires can be used for wires that do not need to carry large currents (e.g. signal wires). In other words, wires that need to carry large currents will have a smaller width and therefore consume less surface area, which implies an increased packing density.

The semiconductor device according to the invention provides an additional advantage. In lithography it is difficult to print different feature sizes in a single shot. For example, if, at a 45-nm technology node having a minimum wire width/spacing of 90-nm/90-nm, the lithography process is optimized for minimum wire width and spacing, the printing of features with sizes ranging from 100-nm up to 150-nm wide might not be optimized. This is especially a problem for so-called “dry lithography” processes. The semiconductor device according to the invention suffers less from the lithography problem described above, because the wires that need to carry large currents will have a smaller width than in the prior art (and in some cases even minimum width). Therefore, these thicker wires (having a smaller width) will be printed better than the thinner wires in the prior art (having a larger width).

In the following, preferred embodiments of the semiconductor device according to the invention will be presented. The embodiments can be combined with each other, unless explicitly stated otherwise.

In a preferred embodiment of the semiconductor device according to the invention at least one of the first wire and the second wire is provided with a via. A via enables electrical connection of one wire to another wire or of one wire to an active element (transistor and diode). In an advantageous improvement of the latter embodiment of the semiconductor device according to the invention the interconnect layer is a dual-damascene interconnect layer. A dual-damascene interconnect layer is a layer which comprises a wire having a via, wherein the wire and the via have been provided in one step. The biggest advantage of dual-damascene interconnect is its lower production costs. For example, during manufacturing of a copper interconnect layer two chemical-mechanical processing (CMP) steps are saved (metal CMP and barrier CMP). Also a few deposition steps (dielectric, copper barrier, copper fill) are saved. CMP is a very expensive step in IC manufacturing. Another advantage of dual-damascene interconnect is that the contact resistance of the connection between a wire and a via is lower. The main reason behind this is that there are fewer interfaces between the wire and the via. In case of a copper interconnect structure the barrier layer is no longer present between the wire and the via which also improves the reliability of this connection.

With the method according to the invention the second object is realized in that the method comprises steps of:
providing the substrate having the surface, the substrate being provided with an insulating layer at the surface, the insulating layer being provided with a patterned masking layer thereon;
forming a first trench and a second trench in the insulating layer, the first trench and the second trench being formed by locally removing the insulating layer using the patterned masking layer as a mask, the first trench defining the first wire having a first thickness, the second trench defining the second wire having a second thickness, wherein the removal of the insulating layer is locally delayed by means of a further masking layer, whereby the second wire to be formed will get a different thickness from the first wire to be formed, the thickness being defined in a direction perpendicular to said surface; and
providing a conductive material in the first trench and the second trench for forming the first wire and the second wire.

The method according to the invention provides a convenient way of forming the semiconductor device and reflects the advantages achieved with the semiconductor device of the invention.

In the following, preferred embodiments of the method according to the invention will be presented. As before, the embodiments can be combined with each other, unless explicitly stated otherwise.

In a first main variant of the method according to the invention the further masking layer is provided between the insulating layer and the masking layer. The further masking layer can then be utilized to locally delay the removal of the insulating layer at locations where the patterned masking layer has openings.

Preferably, in this embodiment the patterned masking layer and the further masking layer are hard masks. Using a hard mask for both the patterned masking layer and the further masking layer is advantageous, because hard masks are generally very thin and provide better defined patterning than photoresist layers.

In a second main variant of the method according to the invention the further masking layer is provided on top of the patterned masking layer. The further masking layer can then be utilized to locally delay the removal of the insulating layer at locations where the patterned masking layer has openings.

Preferably, in this embodiment the patterned masking layer is a hard mask and the further masking layer is a photoresist layer. This embodiment is advantageous, because it saves a few process steps when compared with the embodiment wherein the masking layer and the further masking layer are both hard masks. The first step that is saved is a hard mask deposition step (provision of the further masking layer). The second step is the a hard mask etching step (transfer of a pattern from a photo resist layer onto the hard mask).

In a preferred embodiment of the method according to the invention, the method comprises the step of forming holes in the insulating layer for defining vias. Vias are advantageous for forming connections between wires in different interconnect layers. In a first variant on the preferred embodiment of the method the holes are formed before forming of the first trench and the second trench. In a second variant of the preferred embodiment of the method the holes are formed after formation of the first trench and the second trench, but before provision of the conductive material. The skilled person may choose the variant which best fits his process technology.

A further improvement of last three embodiments of the method according to the invention is characterized in that in the step of providing a conductor material in the first trench and the second trench, also the holes are filled. This feature makes the method according to the invention compatible with most dual damascenes processes.

Any of the additional features can be combined together and combined with any of the aspects. Other advantages will be apparent to those skilled in the art. Numerous variations and modifications can be made without departing from the scope of the claims of the present invention. Therefore, it should be clearly understood that the present description is illustrative only and is not intended to limit the scope of the present invention.

How the present invention may be put into effect will now be described by way of example with reference to the appended drawings, in which:

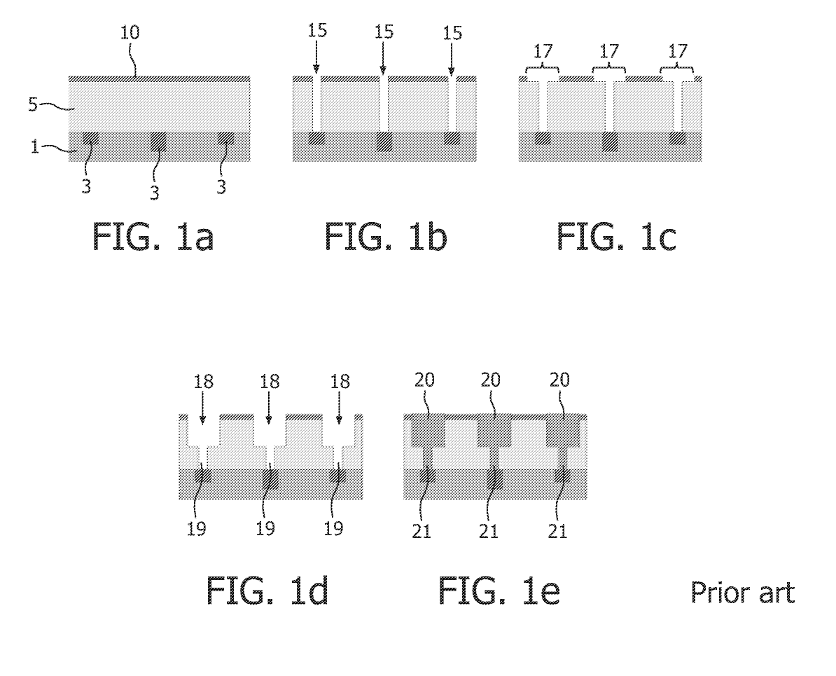

FIGS. 1a-1e illustrate different stages of a known method of manufacturing a semiconductor device;

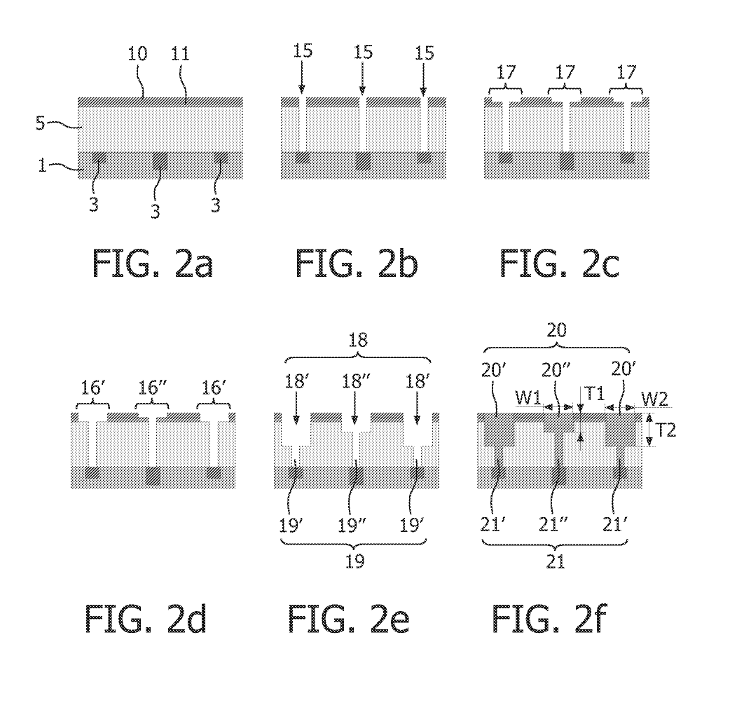

FIGS. 2a-2f illustrate different stages of a first embodiment of the method of manufacturing a semiconductor device according to the invention;

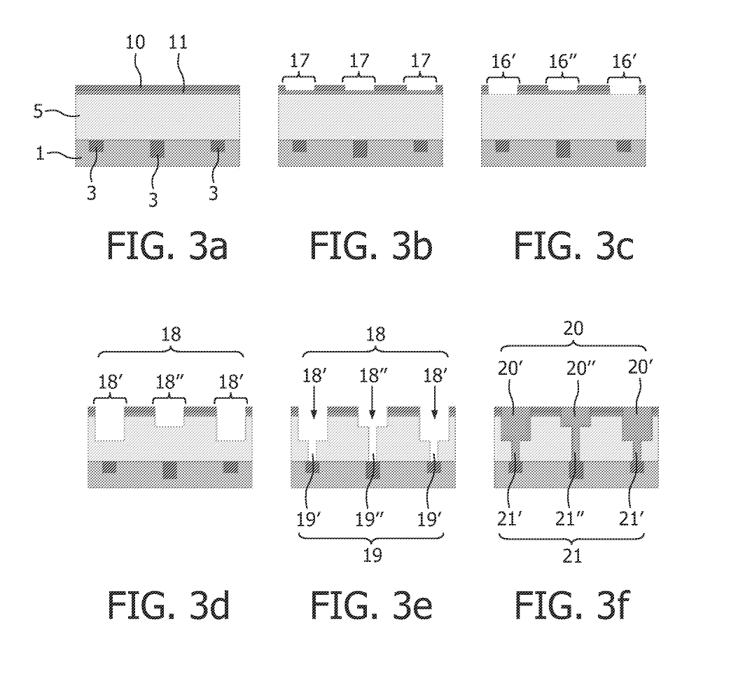

FIGS. 3a-3f illustrate different stages of a second embodiment of the method of manufacturing a semiconductor device according to the invention; and

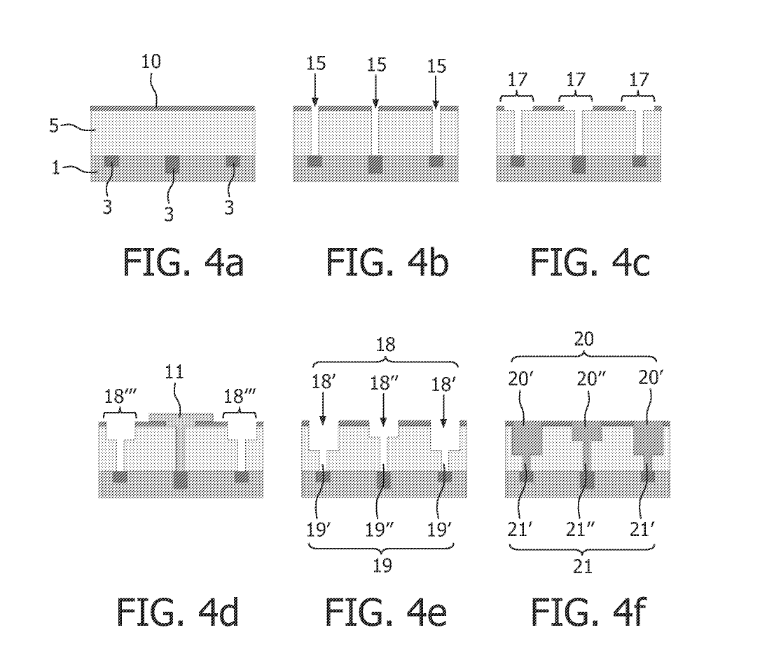

FIGS. 4a-4f illustrate different stages of a third embodiment of the method of manufacturing a semiconductor device according to the invention.

Referring to FIGS. 1a-1e, these figures illustrate different stages of a known method of manufacturing a semiconductor device having wires in an interconnect layer. FIGS. 1a-1e are schematically cross-sectional. FIG. 1a illustrates a first stage of the known method. In this stage a layer stack is provided comprising a substrate 1, an insulating layer 5 being provided on the substrate, and a masking layer 10 being provided on the insulating layer 5. The substrate 1 comprises conductive elements 3 which can be wires, diffusion areas in a substrate, or wires in a substrate for example.

In embodiments of the present invention, the term “substrate” may include any underlying material or materials that may be used, or upon which a device, a circuit or an epitaxial layer may be formed. In other alternative embodiments, this “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a SiO₂ or an Si₃N₄ layer in addition to a semiconductor substrate portion. Thus, the term substrate also includes glass, plastic, ceramic, silicon-on-glass, silicon-on sapphire substrates. The term “substrate” is thus used to define generally the elements for layers that underlie a layer or portions of interest. Also, the “substrate” may be any other base on which a layer is formed, for example a glass or metal layer. Hence, this substrate layer can be any material that is suitable for inlaying a damascene structure, including an oxide layer such as silicon dioxide or TEOS for example. It can be formed on top of other underlying layers, including substrates and semiconductor or conductive layers.

The insulating layer 5 may comprise materials such as: silicon oxide (SiO₂), Black Diamond™, Orion™, Aurora™, Silk™, p-Silk™ and other low-dielectric constant materials being investigated or used in IC manufacturing processes. The insulating layer 5 can be made of one dielectric material or a combination of multiple layers of different dielectric materials.

The masking layer 10 is preferably a hard mask. Suitable materials for a hard mask are silicon oxide (SiO₂), silicon carbide (SiC), silicon nitride (Si₃N₄), titanium oxide (Ti₂O₃), tantalum nitride (TaN), tantalum, and titanium. The first three are dielectrics and the last three are metal hardmasks. Titanium oxide (Ti₂O₃) is created by depositing titanium and then oxidizing it with oxygen plasma.

FIG. 1b illustrates another stage of the known method. In this stage contact holes 15 are formed in the insulating layer 5 (thus patterning the masking layer 10). The via holes 15 extend through the masking layer 10 and the insulating layer 5 as far as the conductive elements 3. The via holes 15 can be formed using conventional etching techniques known by the person skilled in the art.

FIG. 1c illustrates another stage of the known method. In this stage the masking layer 10 is further patterned such that at the location of the via holes 15 enlarged openings 17 are formed in the masking layer 10. The patterning may be carried out using conventional techniques known by the person skilled in the art, e.g. microlithography using a photoresist layer.

FIG. 1d illustrates another stage of the known method. In this stage wire trenches 18 are formed using the masking layer 15 as a mask. The wire trenches 18 can be formed using conventional etching techniques known to a person skilled in the art. As a result of this step in the method original via holes 15 are converted into via holes 19 which are less deep with respect to the bottom of the wire trenches 18.

FIG. 1e illustrates another stage of the known method. In this stage wires 20 and vias 21 are formed in the wire trenches 18 and via holes 19. This can be done by means of deposition of a conducting layer followed by a CMP or etching step, for example. These are conventional techniques known by the person skilled in the art. The conducting layer may comprise materials such as Aluminum, Copper, etc. In the case of the use of Copper barrier layers may be needed to encapsulate the copper wires. Barrier layers are then typically provided before the provision of the conducting layer. The manufacturing and use of barrier layers is known by the person skilled in the art. In the example in FIG. 1e the wires 20 and the vias 21 are preferably filled in one step, which makes the process a dual-damascene process.

The method illustrated in FIGS. 1a-1e is also known as a via-first dual-damascene process. The words “via-first” mean that the via holes 15,19 are formed before the wire trenches 18 are formed. Alternatively, the via holes 15, 19 can be formed after the wire trenches 18, which makes the method a so-called “via-last” dual damascene process.

In this particular example vias 21 are present in all wires 20 shown. However, this is just done for the purpose of illustration. Vias 21 are normally only formed there where a contact with a conducting element 3 in a lower interconnect layer is needed. This statement is also valid for the embodiments of the invention that will be discussed later.

Material choices as described in for FIGS. 1a-1e are also valid for the embodiments of the invention.

Also, in this particular example wires are extending in a direction perpendicular to the cross-sectional view. Obviously, in realality design wires may extend in other directions as well. This statement also holds for the embodiments of the invention that will be discussed later.

Wherever the word “via” is used in this specification, also a “contact” may be meant. A possible convention, also being the preference of the inventors, is to call a connection between two different interconnect layers a via and a connection between an interconnect layer and a substrate (e.g. a diffusion region) a contact.

Furthermore, it is essential for the invention that the via 21 be not considered part of the wire 20. The via 21 does not extend significantly in the direction perpendicular to the cross-sectional view of the FIG. 1e. In most cases the vias 21 are square or rectangular, but this is not essential. Moreover, one wire may have multiple vias to the conductive elements 3 in order to reduce the parasitic contact resistance. In this specification, the wire 20 is defined as that part of the conducting structure (20,21) that carries current in its current-flow direction (in this specification perpendicular to the cross-sectional view).

Referring to FIGS. 2a-2f, these figures illustrate different stages of a first embodiment of the method of manufacturing a semiconductor device according to the invention. The semiconductor device comprises wires in an interconnect layer. FIGS. 2a-2e are schematical cross-sectional views.

FIG. 2a illustrates a first stage of the first embodiment of the method according to the invention. In this stage a layer stack is provided comprising a substrate 1, an insulating layer 5 being provided on the substrate, and a masking layer 10 being provided on the insulating layer 5. This embodiment of the method according to the invention is characterized by the presence of a further masking layer 11 which is provided between the insulating layer 5 and the masking layer 10. The substrate 1 comprises conductive elements 3 which can be wires, diffusion areas in a substrate, or wires in a substrate for example.

FIG. 2b illustrates another stage of the first embodiment of the method according to the invention. In this stage contact holes 15 are formed in the insulating layer 5 (thus patterning the masking layer 10). The via holes 15 extend through the masking layer 10 and the insulating layer 5 as far as the conductive elements 3. The via holes 15 can be formed using conventional etching techniques known by the person skilled in the art.

FIG. 2c illustrates another stage of the first embodiment of the method according to the invention. In this stage the masking layer 10 is further patterned such that at the location of the via holes 15 enlarged openings 17 are formed in the masking layer 10. The patterning may be carried out using conventional techniques known by the person skilled in the art, e.g. microlithography using a photoresist layer.

FIG. 2d illustrates another stage of the first embodiment of the method according to the invention. In this stage the further masking layer 11 is further patterned such that at the location of some of the via holes 15 enlarged openings 16′ are formed in the further masking layer 11. At the location of another via hole 15 the further masking layer 11 is not further patterned thus resulting in a smaller opening 16″ in the further masking layer 11. This embodiment of the method according to the invention is characterized by the fact that at some locations 16′ enlarged openings are formed in both the masking layer 10 and the further masking layer 11, and in that enlarged openings are only formed in the masking layer 10 at another location 16″. The patterning may be carried out using conventional techniques known by the person skilled in the art, e.g. microlithography using a photoresist layer.

FIG. 2e illustrates another stage of the first embodiment of the method according to the invention. In this stage wire trenches 18 are formed using the masking layer 15 as a mask. The wire trenches 18 can be formed using conventional etching techniques known to a person skilled in the art. It is preferred for the invention that during the formation of the wire trenches 18 the removal of material is anisotropic and selective to both the material of the further masking layer 10 as well as the material of the insulating layer 5. In case the further masking layer is a hard mask, the hard mask should preferably have an etch rate lower than that of the insulating layer under the same etching conditions. The requirement of lower etch rate of the second hard mask layer is to ensure that a thin hard mask layer is sufficient for slowing down the etching of material of the insulating layer. Thin hard masks are preferred to avoid patterning over excessive topography tissue. By doing so trenches will be formed having different depths. At locations 16′ where both the masking layer 10 and the further masking layer 11 have enlarged openings deep wire trenches 18′ will be formed. At another location 16″ where only the masking layer 10 has a large opening a less deep wire trench 18″ will be formed. Effectively, at the other location 16″, the removal of the material of the insulating layer 5 is delayed, so that the trench in the insulating layer 5 will be less deep. A requirement for the latter is that the formation of the trench is stopped after a predefined time period, or that the trenches are not extending towards a lower layer which acts as an etch stop layer. During this step the original via holes 15 are converted into via holes 19 that are less deep with respect to the bottom of the trenches 18. Moreover, two different via holes will be formed. At locations of the deep wire trenches 18′, the via holes 19′ will be less deep than at locations of the less deep wire trench 18″, where a deeper via hole 19″ is formed.

FIG. 2f illustrates another stage of the first embodiment of the method according to the invention. In this stage wires 20 and vias 21 are formed in the wire trenches 18 and via holes 19. This can be done by means of deposition of a conducting layer followed by a CMP or etching step, for example. These are conventional techniques known by the person skilled in the art. In this step, in the deep wire trenches 18′ thicker wires 20′ will be formed having a larger wire thickness T2, and in the less deep wire trench 18″ a thinner wire 20″ will be formed having a smaller wire thickness T1. Also, in the deeper via hole 19″ a thicker via 21″ will be formed, and in the less deep via holes 19′ a thinner via 21′ will be formed.

In the embodiment in FIG. 2f the width W2 of the thicker wires 20′ is the same as the width W1 of the thinner wire 20′. However, these widths can be designed differently. For example, in case the current density of the thicker wires 20′ would be still too high, their width W2 can be further increased, which further reduces the current density. However, this is at the expense of chip area.

For all embodiments of the invention, the wire thickness T1,T2 is defined as the dimension of the wider part of the wire 20 measured in the direction in which the via extends, perpendicular to the plane in which the layers of the stack extend.

For all embodiments of the invention, the wire width W1,W2 is defined as the dimension of the wider part of the wires 20′,20″ perpendicular to the current flow direction and in the same plane as the plane in which the layers of the stack extend. The method illustrated in FIGS. 2a-2f is a via-first dual-damascene process.

Referring to FIGS. 3a-3f, these figures illustrate different stages of a second embodiment of the method of manufacturing a semiconductor device according to the invention. The semiconductor device comprises wires in an interconnect layer. FIGS. 3a-3f are schematical cross-sectional views. The second embodiment of the method according to the invention resembles the first embodiment to a large extent. Here the discussion will mainly be limited to the differences. Where nothing specific is described the same applies as in the description of the first embodiment.

FIG. 3a illustrates a first stage of the second embodiment of the method according to the invention. This stage fully complies with the stage illustrated in FIG. 2a.

FIG. 3b illustrates another stage of the second embodiment of the method according to the invention. This stage partly complies with the stage illustrated in FIG. 2c. In this stage enlarged openings 17 are directly formed in the masking layer 10. The main difference from the stage in FIG. 2c is that no via holes 15 have been formed yet.

FIG. 3c illustrates another stage of the second embodiment of the method according to the invention. This stage partly complies with the stage illustrated in FIG. 2d. The main difference from the stage in FIG. 2d is that no via holes 15 have been formed yet.

FIG. 3d illustrates another stage of the second embodiment of the method according to the invention. This stage partly complies with the stage illustrated in FIG. 2e. The main difference from the stage in FIG. 2e is that no via holes 15 have been formed yet.

FIG. 3e illustrates another stage of the second embodiment of the method according to the invention. This stage partly complies with the stage illustrated in FIG. 2b. The main difference from the stage in FIG. 2b is that via holes 19 are now formed at a moment where the wire trenches 18 have already been formed. By doing so a deeper via hole 19″ and less deep via holes 19′ are directly formed.

FIG. 3f illustrates another stage of the second embodiment of the method according to the invention. This stage fully complies with the stage illustrated in FIG. 2f. The method illustrated in FIGS. 3a-3f is a via-last dual-damascene process.

Referring to FIGS. 4a-4f, these figures illustrate different stages of a third embodiment of the method of manufacturing a semiconductor device according to the invention. The semiconductor device comprises wires in an interconnect layer. FIGS. 4a-4f are schematical cross-sectional views. The method illustrated in FIGS. 4a-4f is a via-first dual-damascene process.

FIG. 4a illustrates a first stage of the third embodiment of the method according to the invention. This stage partly complies with the stage illustrated in FIG. 2a. The main difference from the stage in FIG. 2a is that no further masking layer is provided in this stage yet.

FIG. 4b illustrates another stage of the third embodiment of the method according to the invention. This stage partly complies with the stage illustrated in FIG. 2b. The main difference from the stage in FIG. 2b is that no further masking layer is provided in this stage yet.

FIG. 4c illustrates another stage of the third embodiment of the method according to the invention. This stage fully complies with the stage illustrated in FIG. 2c. The main difference from the stage in FIG. 2c is that no further masking layer is provided in this stage yet.

FIG. 4d illustrates another stage of the third embodiment of the method according to the invention. This stage fully complies with the stage illustrated in FIG. 2d. In fact, in this embodiment the provision of the further masking layer 11 is delayed until this stage. In FIG. 4d the further masking layer 11 has been provided and patterned. In this embodiment the further masking layer can be a photoresist layer. After this patterning of the further masking layer 11, preliminary non-deep wire trenches 18″′ are formed, for example by means of etching techniques. While doing so the further masking layer 11 is “consumed” as well.

FIG. 4e illustrates another stage of the third embodiment of the method according to the invention. This stage fully complies with the stage illustrated in FIG. 2e. However, the way this stage has been achieved slightly differs from FIG. 2e. FIG. 4d shows a stage where the further masking layer 11 is not yet fully removed. But when the removal is continued, the further masking layer 11 will completely disappear and the wire trenches 18″′ will become the deeper wire trenches 18″. However, in this particular embodiment the further masking layer 11 will be stripped, and then the formation of the deeper wire trenches 18′ will be continued. This also results in the formation of the less deep wire trench 18″.

FIG. 4f illustrates another stage of the third embodiment of the method according to the invention. This stage fully complies with the stage illustrated in FIG. 2f. As illustrated in the third embodiment (FIGS. 4a-4f), the key point is also to locally delay the etching of dielectric material during the process. In this embodiment this is realized by using just one extra lithography step after the first hard mask patterning. Preferably photoresist is used as the further masking layer. In that case the remaining photo-resist after development will act as the masking layer for slowing down the etching of low-k layer in some areas. In doing so, the number of processing steps can be reduced from the first and second embodiments that use an additional hard-mask layer.

The invention thus provides a semiconductor device, which has an interconnect layer with at least two wires having a different wire thickness, wherein the packing density can be improved by implementing the wires carrying a high current density in thicker wires than the wires carrying a lower current density. This advantage is gained at the cost of a few additional process steps, but the costs of these steps are expected to be low. And more importantly, the cost gained due to smaller circuit area might be even larger than the cost of added process steps.

The invention also provides a method of manufacturing such a semiconductor device.

Many variations on the discussed embodiments of the method according to the invention are possible. All variations fall under the scope of the claims. For example, a fourth embodiment of the method according to the invention is a modification of the third embodiment. Instead of forming the via holes early in the process, the formation is then done after the formation of the wire trenches, which makes the process a “via-last” process more similar to the second embodiment of the method. Furthermore, in all discussed embodiments the process was sort of a dual damascene process, as far as the trench filling is concerned. Obviously, such an approach is not essential to the invention. Single damascene processes and other variations are also possible. In the examples given the insulating layer comprised one single layer. A variation on this can be that the insulating layer comprises multiple layers, eventually being made of different materials. Also, in all examples two masking layers were used. However, more masking layers (preferably all hard masks) can be used as well. This feature allows the formation of wires having more than two different wire thicknesses. Another variation may comprise the use of airgaps in the insulating layer. Another category of variations is related to the number of wires. All given examples comprise stacks having a interconnect layer with 3 wires. Obviously, any number of wires falls under the scope of the claims, as long as the interconnect layer comprises at least two wires having a different wire thickness. Throughout the specification the use of polysilicon material in the fuse body has been mentioned. However, the skilled person may be able to find alternative materials later on, which are also suitable for semiconductor fuse structures. Therefore, these kind of variations have to be regarded as equivalents to polysilicon and do not depart from the scope op the invention which is defined by the claims.

The present invention has been described with respect to particular embodiments and with reference to certain drawings, but the invention is not limited thereto but only by the claims. Any reference signs in the claims shall not be construed as limiting the scope. The drawings described are only schematic and are non-limiting. In the drawings, the size of some of the elements may be exaggerated and not drawn to scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

1. A semiconductor device comprising a substrate and at least one interconnect layer located at a surface of the substrate, the interconnect layer comprising a first wire and a second wire which are located in the interconnect layer, the first wire having a first thickness and the second wire having a second thickness that is different from the first thickness, the thickness being defined in a direction perpendicular to said surface.

2. A semiconductor device according to claim 1, characterized in that at least one of the first wire and the second wire is provided with a via.

3. A semiconductor device according to claim 2, characterized in that the interconnect layer is a dual-damascene interconnect layer.

4. A method of manufacturing a semiconductor device comprising a substrate and an interconnect layer located at a surface of the substrate, the interconnect layer comprising a first wire and a second wire which are located in the interconnect layer, the method comprising steps of:
providing the substrate having the surface, the substrate being provided with an insulating layer at the surface, the insulating layer being provided with a patterned masking layer thereon;
forming a first trench and a second trench in the insulating layer, the first trench and the second trench being formed by locally removing the insulating layer using the patterned masking layer as a mask, the first trench defining the first wire having a first thickness, the second trench defining the second wire having a second thickness, wherein the removal of the insulating layer is locally delayed by means of a further masking layer, whereby the second wire to be formed will get a different thickness from the first wire to be formed, the thickness being defined in a direction perpendicular to said surface; and
providing a conductive material in the first trench and the second trench for forming the first wire and the second wire.

5. A method as claimed in claim 4, characterized in that the further masking layer is provided between the insulating layer and the masking layer.

6. A method as claimed in claim 5, characterized in that the patterned masking layer and the further masking layer are hard masks.

7. A method as claimed in claims 4, characterized in that the further masking layer is provided on top of the patterned masking layer.

8. A method as claimed in claim 7, characterized in that the patterned masking layer is a hard mask and the further masking layer is a photoresist layer.

9. A method as claimed in any one of claims 4 to 8, characterized in that the method comprises the step of forming holes in the insulating layer for defining vias.

10. A method as claimed in claim 9, characterized in that the holes are formed before formation of the first trench and the second trench.

11. A method according to claim 9, characterized in that the holes are formed after formation of the first trench and the second trench, but before provision of the conductive material.

12. A method as claimed in claim 9, characterized in that during the step of providing a conductor material in the first trench and the second trench, also the holes are filled.
